(19) United States
(12) Patent Application Publication
(10) Pub. No.: US 2013/0013245 A1
(43) Pub. Date: Jan. 10, 2013

(54) METHOD FOR OBTAINING DISTRIBUTION OF CHARGES ALONG CHANNEL IN MOS TRANSISTOR

(75) Inventors: Ru Huang, Beijing (CN); Dong Yang, Beijing (CN); Fei Tan, Beijing (CN); Xia An, Beijing (CN); Xing Zhang, Beijing (CN)

(73) Assignee: PEKING UNIVERSITY, Beijing (CN)

(21) Appl. No.: 13/499,275

(22) PCT Filed: Oct. 28, 2011
(86) PCT No.: PCT/CN11/81475

§ 371 Date: Mar. 29, 2012

(30) Foreign Application Priority Data
Mar. 7, 2011 (CN) 201110053772.8

(51) Int. Cl. G01R 31/26; G06F 19/00

(52) U.S. Cl. 702/108; 324/762.01

(57) ABSTRACT

The present invention discloses a method for obtaining a distribution of charges along a channel of a MOS transistor, which is used for obtaining distributions of interface states charges and charges of a gate dielectric layer in the MOS transistor. The method includes: adding a MOS transistor into a test circuit; measuring two charge pumping current curves when a source terminal is open-circuited or when a drain terminal is open-circuited before and after a stress is applied by using a charge pumping current test method, where one of the two charge pumping current curves is an original curve and the other one is an post-stress curve; finding a point B corresponding to a point A on the original curve on the post-stress curve, and estimating amount of locally-generated interface states charges and charges of the gate dielectric layer by a variation of the charge pumping current and a variation in a voltage at a local point. As compared with a conventional method for obtaining a distribution, the method of the present invention can obtain a distribution of charges along a direction form the drain or source terminal to the channel more easily and rapidly, with an aid of a computer. A mass of complicated and repeated tests are reduced. Also, the method can provide an effective base for improving device reliability.

### CROSS-REFERENCES TO RELATED APPLICATIONS

This is a U.S. national phase application of PCT/CN2011/081475, filed Oct. 28, 2011, which claims priority to Chinese Patent Application No. 201110053772.8, filed Mar. 7, 2011 incorporated by reference in its entirety.

### FIELD OF THE INVENTION

The present invention relates to a semiconductor device test field, particularly relates to a method for obtaining distributions of interface state charges and charges of a gate dielectric layer in a MOS transistor for testing.

### BACKGROUND

In recent decades, as an integration degree of a circuit is increased, the size of a device is also gradually reduced into a deep sub-micrometer level, even into a nanometer level. However, the reduction of the feature size of the device results in various reliability problems, including HCE (hot carrier effect, NBTI (Negative Bias Temperature Instability), TDDB (Time-Dependent Dielectric Breakdown) and so on. A main reason for the reliability problems is that an externally applied stress causes some traps generated at the Si/SIO2 interface and in the gate dielectric layer of the device, which adversely affects the performance of the small-size device. Therefore, precisely measuring the density of interface charges and the gate dielectric charges is very important for a research of the reliability of the device.

Due to a fact that charges density of the gate dielectric layer and charges density at the interface generated under the external stress are not uniformly distributed, it is very difficult to reliably and precisely measure traps distribution generated under the external stress in the device by using a conventional method such as Intermediate Band Threshold Voltage (IBTV) method, Capacitance-Voltage (C-V) method, Conductance method, Deep Level Transient Spectroscopy (DLTS) method, and Random Telegraph Noise (RTN) method. However, a widely-used method for measuring the traps density generated at interface and gate dielectric layer is charge pumping method.

In 1969, J. Stephen. Brugler proposed the charge pumping method. The main principle of the charge pumping method is shown in FIG. 1, the source and drain terminals of a device are applied with a reverse bias voltage simultaneously, while the gate of the device is applied with a pulse voltage. When the gate of a NMOS device is applied with a positive pulse voltage which is higher than a threshold voltage Vth so that a surface is deeply depleted to enter into an inversion state, electrons will flow into a channel from the source/the drain, where some of the electrons will be captured by interface traps. When the pulse voltage at the gate is lower than a flat band voltage Vfb so that the surface returns to an accumulation state, electrons in the channel return to the source/the drain because of the reverse bias. Since the electrons trapped in the interface state have a long escape time constant, the electrons may be trapped in the interface state after the channel is disappeared and consequently recombine with majority carriers from substrate to generate a substrate current Icp. Since a magnitude of the current Icp is very sensitive to the traps at the interface and directly proportional to the interface state density, an area of the gate of the device and a frequency of the pulse at the gate, an variation of traps at the interface will be directly reflected on the Icp, in which the relationship is reflected by the following equation 1.

$$\overline{{D}_{it}} = \frac{{I}_{cp}}{q \times Area \times f \times Δ E} \qquad ( Equation 1 )$$

Where, D̅ᵢ̅ₜ̅ is an average interface state density, q is the basic charge constant, Area is the area of the gate, f is the frequency of the pulse, and ΔE is an energy difference between a Fermi energy level when a silicon surface is inversed and a Fermi energy level when the silicon surface is accumulated.

A VLSI fabrication technology is rapidly developing into a nanometer scale. While a channel length, a junction depth, and a gate oxide layer thickness of a device are scaled down, the power supply voltage is not scaled down, which causes strong local horizontal and vertical electric field. Under such strong local electric field, reliability of a MOS device is faced with a serious challenge, and local charges generated at interface and in the gate dielectric layer are also critical to the device performance. The conventional charge pumping method can only calculate an average of the charge density generated at the whole interface. Although distributions of interface state charges and charges of the dielectric layer along the channel due to the stress may be roughly calculated by changing test conditions and structures, it is necessary to perform a very complicated calculation procedure, and to measure a series of charge pumping curves under different base voltages of the pulse voltage for the gate by constantly changing the magnitude of the pulse for the gate or changing a bias voltage for the source/drain and the substrate, and thus obtain the distribution of respective added charges along the channel according to an obtained maximum current value. Therefore, in a method for obtaining the distribution of interface state charges and charges of the gate dielectric layer along the channel based on the conventional charge pumping method, it is necessary to perform a mass of tests and calculations, thus the procedure is very complicated.

### SUMMARY OF THE INVENTION

An object of the present invention is to provide a method for obtaining the distribution of interface state charges and charges of a gate dielectric layer caused by a stress along a channel in a MOS transistor, based on a charge pumping method.

A technical solution provided by the present invention is as following.

Solution 1 relates to a method for obtaining a distribution of charges along a channel in a MOS transistor, which is used for obtaining the distribution of interface states charges and charges of a gate dielectric layer in the MOS transistor. The method includes the following steps.

a) A test circuit is constructed, so that by using a charge pumping current test method in which a fixed pulse magnitude and a varied base voltage are used, four charge pumping current curves before and after a stress are applied (as shown in FIG. 5), which are measured when a drain terminal of the MOS transistor is open-circuited and when a source terminal is open-circuited, are obtained. In the four charge pumping current curves, a pair of curves are an original curve Origin1 and a post-stress curve Post-stress1 after the stress is applied and measured when the source terminal is open-circuited. The other pair of curves are an original curve Origin2 and a post-stress curve Post-stress2 after the stress is applied, measured when the drain terminal is open-circuited. The two original curves Origin (Origin1 and Origin2) overlap with each other. When using the charge pumping method to measure the charge pumping current curves, the drain terminal and the source terminal are open-circuited respectively, so that a distribution of charges from the source terminal to a center of the channel and a distribution of charges from the drain terminal to the center of the channel can be obtained respectively. A specific diagram of a test circuit is shown in FIG. 1.

b) A point B corresponding to a point A on the original curve (Origin) is found on a post-stress curve (Post-stress), so that quantities of locally-generated interface state charges and charges of the gate dielectric layer are estimated by a variation of a charge pumping current and a variation in a voltage at the local point A.

Solution 2 relates to a preferable implementation of the solution 1. In solution2, the step b) includes the following steps (FIG. 2 is a flow diagram of a method of the solution 2, and an illustration of the flow diagram is shown in FIG. 3).

1) Distributions of threshold voltage Vₜₕ and flat band voltage V_{fb} of local point along the channel are obtained according to the original curve.

Particularly, it is assumed that an original interface state of the MOS transistor before the stress is applied are uniformly distributed (for example, in a case of a good process condition), and the distributions of the threshold voltages Vₜₕ and flat band voltages V_{fb} of the local corresponding point along the channel (equation 2) are obtained according to a curve measured by the charge pumping method before the stress is applied. A result of the distributions are shown in FIG. 4,

I_{cp}(Vₜₕ)=q×f× D̅ᵢ̅ₜ̅×W×x (Equation 2)

wherein, x is a position of a point in the channel, and x is calculated by:

$$x = \frac{L \times {I}_{cp} ( {V}_{th} )}{{I}_{cp , max}} \qquad ( Equation 3 )$$

I_{cp}(Vₜₕ) is a local charge pumping current, I_{cp,max} is a maximum charge pumping current generated by the transistor.

2) The point A in a region I of the curve Origin1 (a left part of a maximum current value of each curve is defined as the region I of the curve, and a right part of the maximum current value of each curve is defined as a region II of the curve) is arbitrarily selected.

3) A point Bᵢ (i=1, 2, 3 . . . ) in the region I of the curve Post-stress1 is enumerated, so as to obtain a variation ΔI_{cp}(x) of a charge pumping current and an offset ΔVₜₕ(x) of a local threshold voltage, and thus a variation ΔNᵢₜ(x) of interface state charges and a variation ΔNₒₜ(x) of charges of the gate dielectric layer from the point A to the point B are calculated (by equation 4 and 5).

$$\begin{matrix}Δ {N}_{it} ( x ) = \frac{Δ {I}_{cp} ( x )}{q \times f \times Area} & ( Equation 4 ) \\ Δ {N}_{ox} ( x ) = \frac{Δ {V}_{th} ( x ) \times {C}_{ox}}{q} + Δ {N}_{it} ( x ) & ( Equation 5 )\end{matrix}$$

where, Cₒₓ is a unit capacitance of the gate dielectric layer.

4) A point C in the region II of the curve Origin1 corresponding to the point A is found, by using the distributions of the local threshold voltage and the local flat band voltage (see FIG. 3c). Moreover, a corresponding point D in the region II of the curve Post-stress1 is found according to expressions of offsets of the threshold voltage and the flat band voltage (equations 6 and 7), where it is assumed that an acceptor-like interface state occupies above a middle of an energy band, and a donor-like interface state occupies below the middle of the energy band.

ΔVₜₕ(x)=qΔNₒₜ(x)/Cₒₓ−qΔNᵢₜ(x)/2Cₒₓ (Equation 6)

ΔV_{fb}(x)=qΔNₒₜ(x)/Cₒₓ+qΔNᵢₜ(x)/2Cₒₓ (Equation 7)

5) A point A′ on the curve Origin2 corresponding to the point A on the curve Origin1 is found from the distribution of the local threshold voltage or the local flat band voltage (see FIG. 3c) (according to the same local threshold voltages or flat band voltages). Moreover, a point C′ in the region II of the curve Origin2 corresponding to the point A′ is found by repeating the step 4.

6) A difference of the charge pumping current between the point B and the point A is recorded as ΔI_{cp1}, and a difference of the charge pumping current between the point D and the point C is recorded as ΔI_{cp2}. Since variations of charge pumping currents caused by the stress at point C and C′ are the same, a difference of the charge pumping current between a point D′ and the point C′ is recorded as ΔI_{cp2}′. The corresponding point D′ in the region II of the curve Post-stress2 is founded according to ΔI_{cp2}′=ΔI_{cp2}.

7) A point B′ in the region I of the curve Post-stress2 corresponding to the point A′ is found, according to the expressions of offsets of the threshold voltage and the flat band voltage (equations 6 and 7) (see the step 4).

8) Since an interface state density generated by the stress is much more than an interface state density at the interface in the case of the good original process condition, during a comparison an influence of the local original interface state is neglected. A charge difference of pumping current between the point B and the point A is recorded as ΔI_{cp1}′, a difference between maximum values of the charge pumping current measured before and after the stress is applied is recorded as ΔI_{cp,max} (current differences of two groups are the same), the point B is enumerated in the region I of the curve Post-stress1 until ΔI_{cp1}+ΔI_{cp1}′+ΔI_{cp2} (or ΔI_{cp2}′)=ΔI_{cp,max};

9) When the corresponding point B is found, the local ΔNᵢₜ(x) and ΔNₒₜ(x), that is, distributions of interface state charges and charges of the gate dielectric layer along the channel, which are added after the stress is applied, are obtained.

Solution 3 relates to a preferable implementation of the solution 1. In the step a), in the test circuit, the source terminal is open-circuited, that is, the source terminal of the MOS transistor is floated, the drain terminal and a substrate are short-connected, and a gate terminal is externally applied with a pulse voltage which has a fixed frequency and magnitude and a varied base voltage V_{base}.

Solution 4 relates to a preferable implementation of the solution 1. In the step a), in the test circuit, the drain terminal is open-circuited, the drain terminal of the MOS transistor is floated, the source terminal and the substrate of the MOS transistor are short-connected, and the gate terminal is externally applied with a pulse voltage which has a fixed frequency and magnitude and a varied base voltage V_{base}.

Solution 5 relates to a preferable implementation of the solution 3 or 4. Particularly, the fixed magnitude of the pulse voltage is larger than a difference between the flat band voltage V_{fb} and the threshold voltage Vₜₕ.

Solution 6 relates to a preferable implementation of the solution 3 or 4. Particularly, the fixed frequency of the pulse voltage is higher than 500 Hz.

Solution 7 relates to a preferable implementation of the solution 1. Particularly, in the step (a), the stress is a hot electron injection stress.

A beneficial effect of the present invention is as followings.

As compared with a conventional method for obtaining a distribution of charges, the method of the present invention can extract a distribution of charges along a direction form the drain or source terminal to the channel more easily and rapidly, with an aid of a computer. A mass of complicated and repeated tests can be reduced. Also, the method can be an effective method for helping determining an improvement of device reliability.

### BRIEF DESCRIPTION OF THE DRAWINGS

FIG. 1 is a principle diagram of an improved charge pumping current test method in which a source terminal is open-circuited.

FIG. 2 is a flow diagram of a method for obtaining a distribution of charges of the present invention.

FIG. 3 are graphs illustrating the flow diagram, in which, FIG. 3a shows a pair of charge pumping current curves before and after a stress is applied, measured when the source terminal is open-circuited; FIG. 3b shows a pair of charge pumping current curves before and after the stress is applied, measured when a drain terminal is open-circuited; FIG. 3c is a graph showing distributions of a local threshold voltage and a local flat band voltage along a channel, before and after the stress is applied.

FIG. 4 is a graph showing original distributions of the local threshold voltage and the local flat band voltage along the channel of a MOS transistor.

FIG. 5 is a graph showing four charge pumping current curves I_{cp}-V_{base} before and after the stress is applied, measured when the source terminal is open-circuited, in which, curves Origin is measured before the stress is applied, where two curves Origin overlap with each other; and curves Post-stress are measured after the stress is applied.

FIG. 6 is a graph showing a distribution of interface state charges caused by the stress along the channel.

FIG. 7 is a graph showing a distribution of charges of the gate dielectric layer caused by the stress along the channel.

### DETAILED DESCRIPTION OF THE PREFERRED EMBODIMENTS

Hereinafter, a preferable embodiment will be described in more detail.

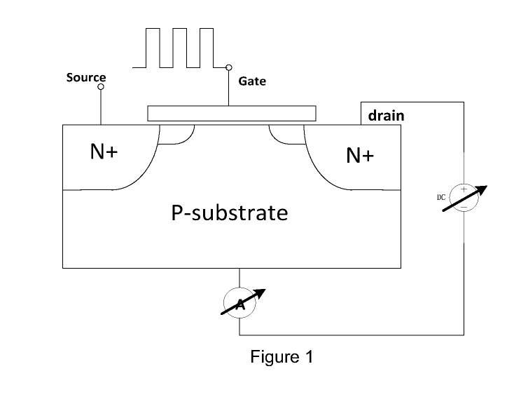

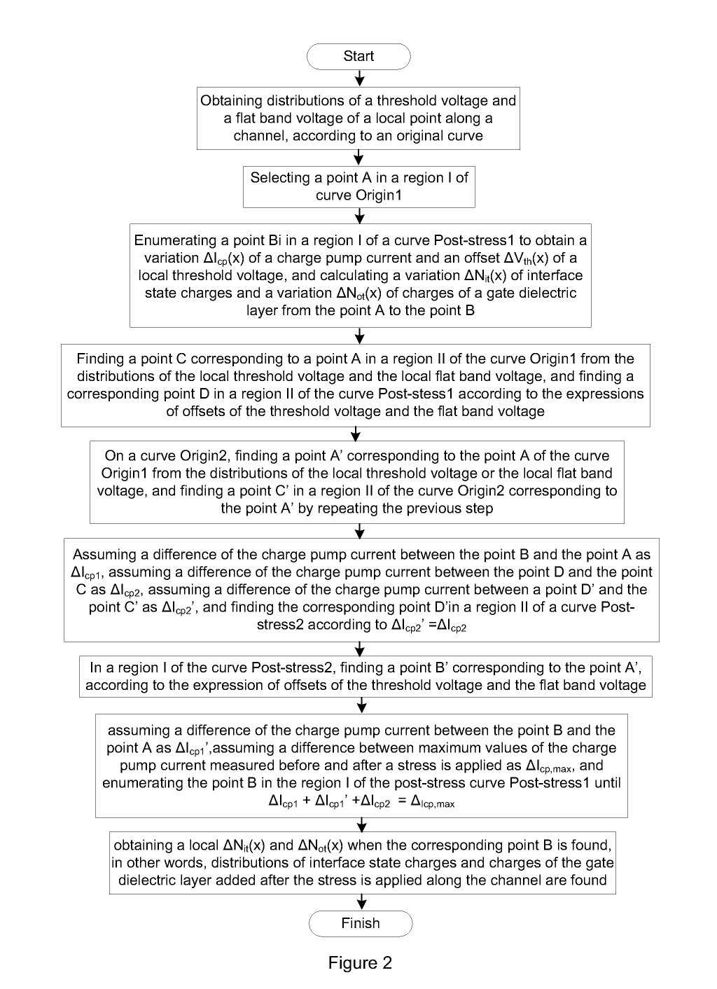

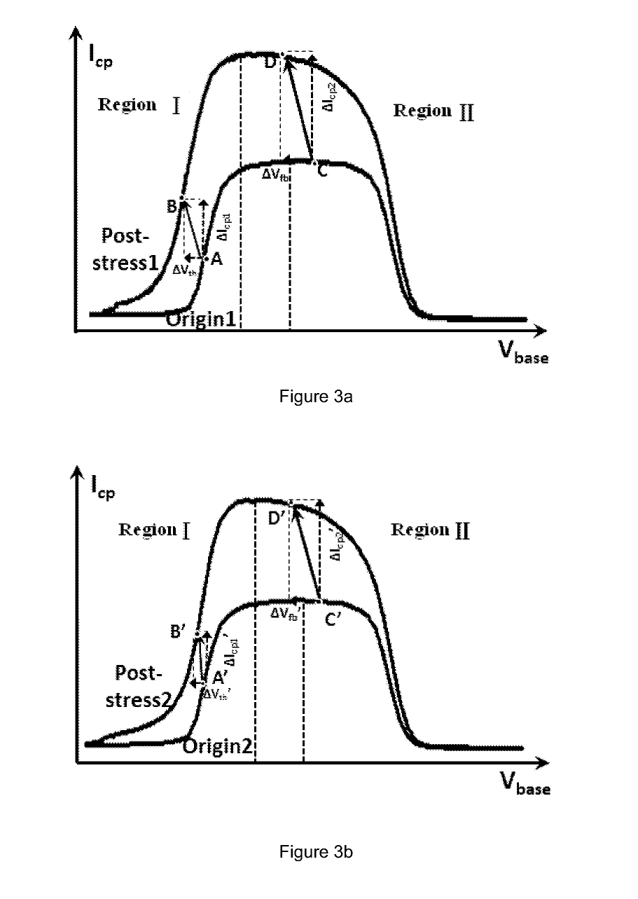

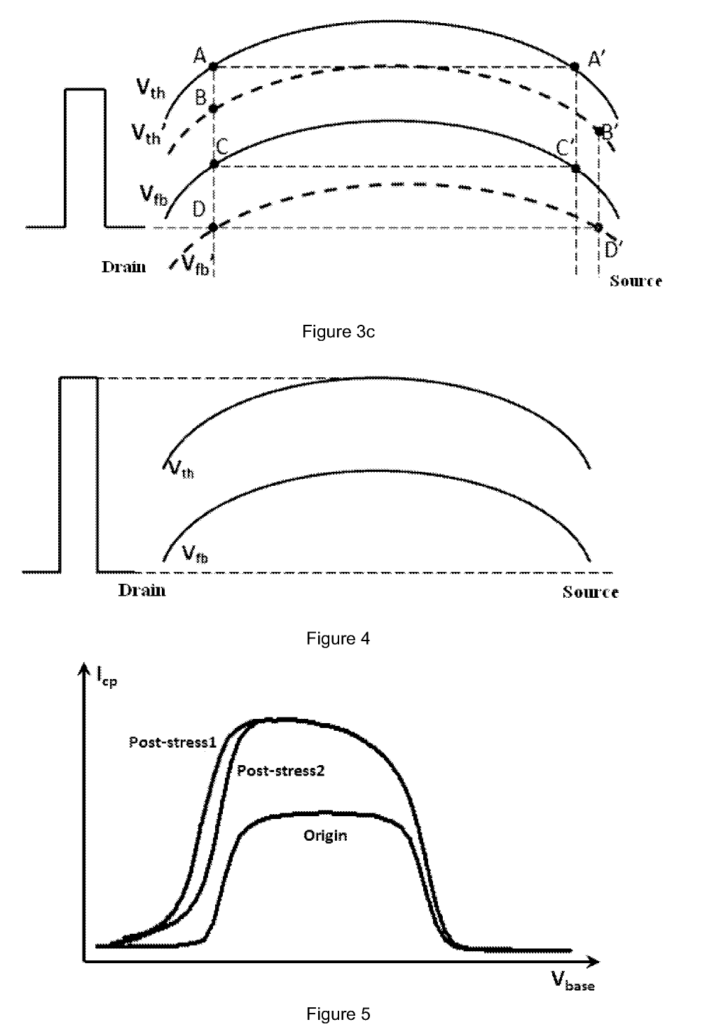

In the present embodiment, a MOS transistor to be tested is a NMOS transistor (similarly, the MOS transistor may be a PMOS transistor). A NMOS transistor having a width (W) of 6 μm and a length (L) of 0.5 μm, which has a good process condition and a uniform interface state, is used. After a hot carrier stress is biased for 1000 s, a test for charges of an interface state and charges of a gate dielectric layer of the transistor is performed. As shown in FIG. 1, a charge pumping current test method, in which one of a source terminal and a drain terminal is open-circuited and the other one is applied with a reverse-bias voltage, is used. A gate is applied with a pulse voltage which has a fixed frequency and a fixed magnitude, where the magnitude of the pulse voltage is larger than a difference between a threshold voltage Vₜₕ and a flat band voltage V_{fb}. Meanwhile, a base voltage is scanned, so that two curves of charge pumping current for two cases, i.e. before and after a stress is applied, are obtained. Referring to FIG. 5, two curves Origin overlap with each other.

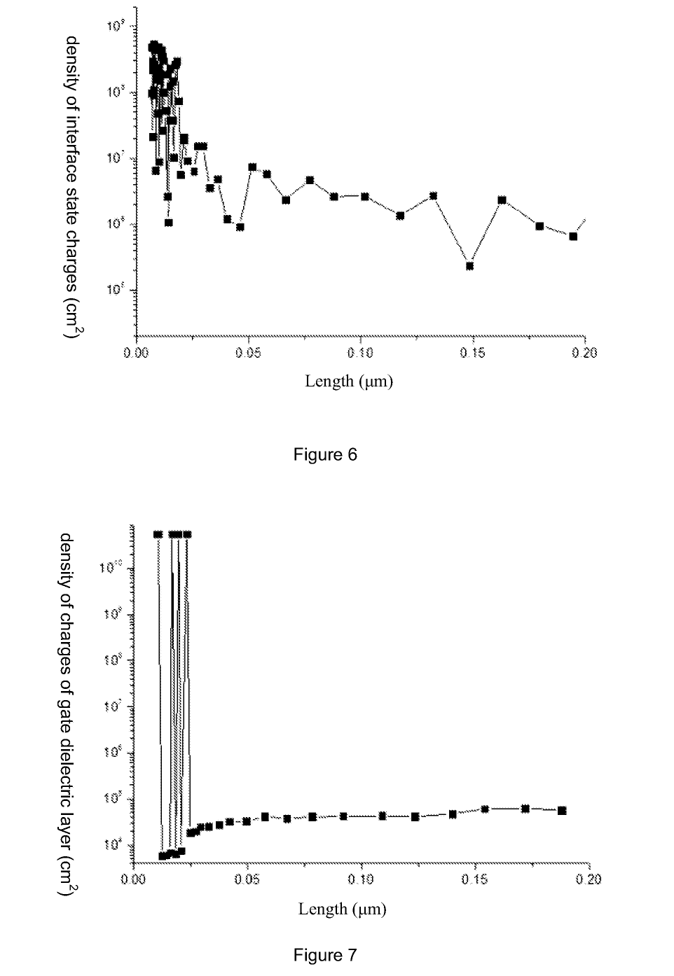

With reference to the method mentioned in above solution 2, graphs (see FIGS. 6 and 7) showing the distribution of the interface state charges and charges of the gate dielectric layer caused by the stress along a direction from the drain terminal to the channel are finally obtained.

In conclusion, by using the method for obtaining distributions of interface state charges and charges of the gate dielectric layer in the MOS transistor, the distributions of interface state charges and charges of the gate dielectric layer along the channel in the MOS transistor after a stress is applied may be rapidly obtained.

I claim:

1. A method for obtaining a distribution of charges along a channel of a MOS transistor, which is used for obtaining distributions of interface state charges and charges of a gate dielectric layer in the MOS transistor, wherein, the method comprises the following steps:
a) constructing a test circuit, and using a charge pumping current test method in which a fixed pulse magnitude and a varied base voltage are used to obtain four charge pumping current curves before and after a stress is applied by open-circuiting a drain terminal of the MOS transistor and a source terminal respectively;
b) finding a point B corresponding to a point A on an original curve on a post-stress curve, so as to estimate amount of locally-generated interface state charges and charges of the gate dielectric layer by a variation of a charge pumping current and a variation in a voltage at the local point A.

2. The method according to claim 1, wherein, the step b) comprises:
1) obtaining a distribution of a threshold voltage Vₜₕ and a flat band voltage V_{fb} of a local point along the channel, according to the original curve;
2) selecting the point A in a region I of an curve Origin1;
3) enumerating a point Bᵢ in a region I of a curve Post-stress1 to obtain a variation ΔI_{cp}(x) of a charge pumping current and an offset ΔVₜₕ(x) of a local threshold voltage, and calculating a variation ΔNᵢₜ(x) of interface state charges and a variation ΔNₒₜ(x) of charges of the gate dielectric layer from the point A to the point B;
4) in a region II of the curve Origin1, finding a point C corresponding to the point A from the distributions of the local threshold voltage and the local flat band voltage, and finding a point D corresponding to the point A in a region II of the curve Post-stress1 according to expressions of offsets of the threshold voltage and the flat band voltage;
5) on a curve Origin2, finding a point A′ corresponding to the point A of the curve Origin1 from the distributions of the local threshold voltage or the local flat band voltage, and finding a point C′ in a region II of the curve Origin2 corresponding to the point A′ by repeating the step 4);
6) assuming a difference of the charge pumping current between the point B and the point A as ΔI_{cp1}, assuming a difference of the charge pumping current between the point D and the point C as ΔI_{cp2}, assuming a difference of the charge pumping current between a point D′ and the point C′ as ΔI_{cp2}′, and finding the corresponding point D′ in a region II of a curve Post-stress2 according to ΔI_{cp2}′=ΔI_{cp2};
7) in a region I of the curve Post-stress2, finding a point B′ corresponding to the point A′, according to the expression of offsets of the threshold voltage and the flat band voltage;
8) assuming a difference of the charge pumping current between the point B and the point A as ΔIcp1′, assuming a difference between maximum values of the charge pumping current measured before and after a stress is applied as ΔIcp,max, and enumerating the point B in the region I of the post-stress curve Post-stress1 until ΔIcp1+ΔIcp1′+ΔIcp2 (or ΔIcp2′)=ΔIcp,max;
9) obtaining a local ΔNit(x) and ΔNot(x) when the corresponding point B is found, in other words, distributions of interface state charges and charges of the gate dielectric layer added after the stress is applied along the channel are found.

3. The method according to claim 1, wherein, in the step a), in the test circuit, the source terminal is open-circuited, in which the source terminal of the MOS transistor is floated, the drain terminal and a substrate are short-connected, and a gate terminal is externally applied with a pulse voltage which has a fixed frequency and magnitude and a varied base voltage V_{base}.

4. The method according to claim 1, wherein, in the step a), in the test circuit, the drain terminal is open-circuited, in which the drain terminal of the MOS transistor is floated, a source terminal and a substrate are short-connected, and a gate terminal is externally applied with a pulse voltage which has a fixed frequency and magnitude and a varied base voltage V_{base}.

5. The method according to claim 3, wherein, the fixed magnitude of the pulse voltage is larger than a difference between the flat band voltage V_{fb} and the threshold voltage Vₜₕ.

6. The method according to claim 3, wherein, the fixed frequency of the pulse voltage is higher than 500 Hz.

7. The method according to claim 1, wherein, in the step (a), the stress is a hot electron injection stress.
